(19) United States
(12) Patent Application Publication
(10) Pub. No.: US 2009/0050194 A1
(43) Pub. Date: Feb. 26, 2009

(54) SUPPORT SYSTEM FOR A PHOTOVOLTAIC SYSTEM

(76) Inventors: Robert L. Noble, Encinitas, CA (US); Nicol M. Zeller, La Jolla, CA (US); William S. Adelson, Ramona, CA (US)

Correspondence Address: NEIL K. NYDEGGER;NYDEGGER & ASSOCIATES, 348 Oliver Street, San Diego, CA, 92103, US

(21) Appl. No.: 11/842,484

(22) Filed: Aug. 21, 2007

(51) Int. Cl. H01L 31/048

(52) U.S. Cl. 136/251

(57) ABSTRACT

A method and modular assembly provide shade and generate electricity using photovoltaic cells. In the method, a kit includes a plurality of columns, a truss assembly, a rack, and a plurality of photovoltaic cells for converting solar energy into electricity. First, four columns are erected at a distance from one another to define an area. Then, the truss assembly is suspended between the columns. Thereafter, the rack is mounted to the truss assembly to form an open roof. To enclose the roof, the photovoltaic cells are arranged on the rack to block sunlight to shade the area, while converting the sunlight to electricity.

### FIELD OF THE INVENTION

The present invention pertains generally to a system for converting solar energy into electricity. More particularly, the present invention pertains to a modular structure for supporting a solar energy conversion system. The present invention is particularly, but not exclusively, useful as a modular structure for supporting photovoltaic cells to convert solar energy into electricity and to shade an area such as a carport.

### BACKGROUND OF THE INVENTION

In view of the depletion of known reserves of fossil fuels, much work has been done in the development of systems for using alternative energy sources. One particularly promising source is solar energy. As a renewable energy source, solar energy is increasingly popular for use as an electricity source. One method of converting solar energy to electricity involves photovoltaic energy systems. These systems use solar cells or solar photovoltaic arrays to convert solar energy directly into electricity.

Substituting renewable energy sources for non-renewable energy sources helps to reduce the harmful ecological impact of fossil fuels. Another manner of reducing that impact is simply by the reduction in need for energy use. For instance, parking lots represent significant heat islands, with localized temperatures that can be 2-10° higher than surrounding areas. Further, the heat from paved areas in urban areas has been shown to even have the power to change the weather locally. Due to the localized increase in urban temperatures, there is an increase in the use of air-conditioning in businesses and homes. Further, the cars parked on exposed parking lots trap heat and require increased use of air-conditioning. Therefore, it would be beneficial to reduce the heat generated at parking lots and within cars to reduce the need for air-conditioning.

In light of the above, it is an object of the present invention to provide modules for supporting elevated photovoltaic cells over parking areas and methods for their construction. It is another object of the present invention to provide modular components for forming structures that convert solar energy into electricity and that provide shaded areas. Yet another object of the present invention is to provide structures with roofs consisting of photovoltaic cells and methods for their manufacture which are easy to use, relatively simple to implement, and comparatively cost effective.

### SUMMARY OF THE INVENTION

The present invention is directed to a kit for constructing modules that provide shade and generate electricity. In the kit, a plurality of columns that may be erected to define an area are provided. Also, the kit includes a truss assembly that is dimensioned for suspension between adjacent columns. Preferably, the columns and truss assembly form conduits that are aligned during construction. Further, the kit includes a rack that may be mounted on the truss assembly for providing an open roof for the area. Finally, the kit includes a plurality of photovoltaic cells for converting solar energy into electricity. When the module is constructed, the cells, whether in panel or array form, are supportable by the rack to close the roof and block sunlight to shade the area.

In certain embodiments, the module is used as a carport for shading a car. In such embodiments, the kit may further includes a cable that passes through the conduits to electrically connect the photovoltaic cells with the car to charge the car with electricity.

Structurally, the rack and the photovoltaic cells may lie in the horizontal plane. However, the rack and photovoltaic cells may be inclined by 10° to face south to receive an optimal amount of solar energy (in the northern hemisphere). Alternatively, the rack may define a plurality of sections that, when erected, extend east-to-west. For such a rack, the sections and the photovoltaic cells are preferably inclined by 20° to face south.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a perspective view of a modular structure in accordance with the present invention being used to shade a car;

FIG. 2 is a perspective view of an alternate embodiment of the modular structure of FIG. 1;

FIG. 3 is a perspective view of a plurality of modular structures constructed adjacent one another in accordance with the present invention;

FIG. 4 is a side view of a modular structure of FIG. 3;

FIG. 5 is a rear end view of the modular structure of FIG. 4; and

FIG. 6 is a side view of another modular structure of FIG. 3.

### DESCRIPTION OF THE PREFERRED EMBODIMENTS

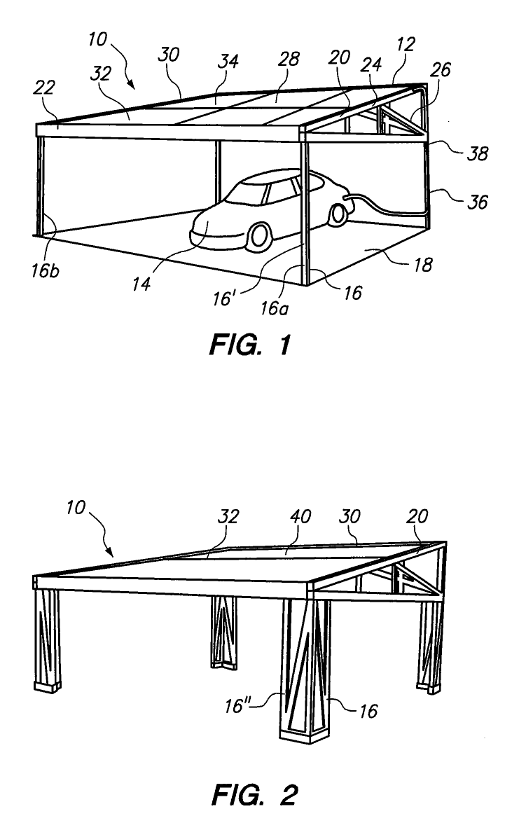

Referring initially to FIG. 1, a modular structure for supporting a photovoltaic system is shown and generally designated 10. In the embodiment shown in FIG. 1, the modular structure 10 serves as a carport 12 for housing a car 14. Structurally, the carport 12 is formed from four columns 16 that are distanced from one another to define an area 18. In FIG. 1, each column 16 is comprised of a single leg 16′. Further, the structure 10 includes a truss assembly 20 that is mounted to and suspended from the columns 16. As shown, the truss assembly 20 includes headers 22 that interconnect adjacent columns (e.g., 16a and 16b). Further, the truss assembly 20 includes rafters 24 and support members 26 to establish an open roof 28 at a desired incline. In the northern hemisphere, the roof 28 is preferably inclined at 10° and faces south.

In FIG. 1, a rack 30 is mounted on the truss assembly 20. Further, photovoltaic cells 32 are positioned in the rack 30. In FIG. 1, the photovoltaic cells 32 are shown as panels 34 in a modular grid, though they may be in sheet form as a solar laminate. Importantly, the photovoltaic cells 32 close the open roof 28 and shade the area 18 enclosed by the structure 10. Further, the photovoltaic cells 32 convert solar energy to electricity. For this purpose, the cells 32 are connected to a cable 36 that runs through a conduit 38 formed in the truss assembly 20 and columns 16. In FIG. 1, the cable 36 is shown connected to the car 14 to charge the car 14 with electricity, however, the cable 36 may be connected to a storage device, to an electricity grid, or to other electrical devices, such as air-conditioners.

Referring now to FIG. 2, an alternate embodiment of the modular structure 10 is shown. In FIG. 2, the structure 10 again is formed from columns 16, a truss assembly 20, a rack 30 and photovoltaic cells 32. However, in FIG. 2, each column 16 is comprised of a trussed leg 16″ to provide increased strength to the structure 10. Further, as shown in FIG. 2, the photovoltaic cells 32 comprise laminate sheets 40 that are supported by the rack 30.

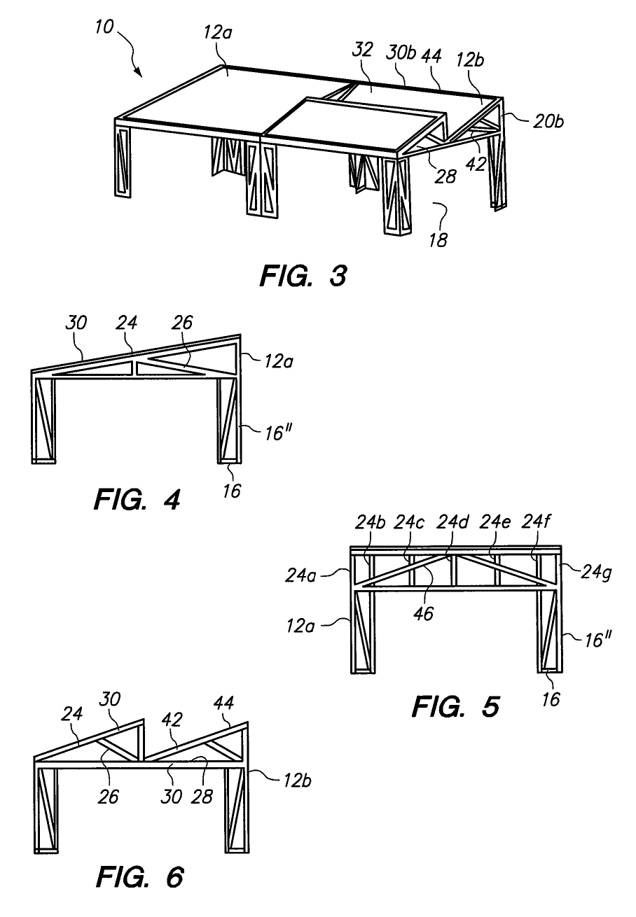

Referring now to FIG. 3, additional aspects of the modular structure 10 may be understood. As shown in FIG. 3, the structure 10 is adapted to include multiple carports 12a,b, with each carport 12a,b defining adjacent areas 18. Further, as shown in FIG. 3, carport 12b includes an alternate embodiment of the truss assembly 20b and rack 30b. As shown, the truss assembly 20b forms an open roof 28 that has sections 42. Preferably, each section 42 is inclined at 20° and faces south (in the northern hemisphere). Accordingly, the rack 30b also includes sections 44 for supporting the photovoltaic cells 32 along the desired incline.

Referring now to FIGS. 4 and 5, the structural components of the carport 12a are illustrated. As shown, the columns 16 in carport 12a are formed from trussed legs 16″. Further, it is to be understood from FIG. 5 that multiple rafters 24a-g and support members (not shown) are positioned periodically between the pairs of columns 16 to provide sufficient structural support to the rack 30. Also, rear supports 46 are provided for structural support.

In FIG. 6, the construction of carport 12b is illustrated. As shown, the truss assembly 20 of carport 12b forms a roof 28 having two sections 42. Accordingly, the rack 30 includes two sections 44 on which photovoltaic cells (not shown in FIG. 6) may be supported at the desired incline.

Regardless of the specific form of the structure 10 in FIGS. 1-6, construction from the building components is relatively easy. As modular structures, each structure 10 is easily positioned and built. Specifically, the columns 16 may be erected on level ground, whether paved or graded, at appropriate distances from one another. Thereafter, the appropriate truss assembly 20 is suspended from the columns 16. Then, the rack 30 is mounted to the truss assembly 20 and the photovoltaic cells 32 are positioned on the rack 30 to close the roof 28. After the cells 32 are electrically connected to a storage device or electrical grid or device, they may convert solar energy into usable electricity while at the same time provide a shaded area 18.

While in the Figures, the structures 10 were illustrated as shading an area 18 suitable to receive a parked car, the structures 10 may be used to provide shaded walkways, roadways, or waiting areas or to reduce the heat received by buildings. In any case, the structures 10 simultaneously create electricity while reducing heat impact.

While the particular Support System for a Photovoltaic System as herein shown and disclosed in detail are fully capable of obtaining the objects and providing the advantages herein before stated, it is to be understood that they are merely illustrative of the presently preferred embodiments of the invention and that no limitations are intended to the details of construction or design herein shown other than as described in the appended claims.

What is claimed is:

1. A modular assembly for providing shade and for generating electricity comprising:
a plurality of columns, with the columns distanced from one another to define an area;
a truss assembly dimensioned for suspension between adjacent columns;
a rack mounted to the truss assembly; and
a plurality of photovoltaic cells for converting solar energy into electricity, with said plurality of cells being supported by the rack to block sunlight to shade the area.

2. An assembly as recited in claim 1 wherein the columns and the truss assembly form conduits for cables electrically connected to the photovoltaic cells.

3. An assembly as recited in claim 1 wherein the rack and photovoltaic cells are inclined by 10°.

4. An assembly as recited in claim 1 wherein the rack defines a plurality of sections, and wherein each section and the photovoltaic cells positioned on each section are inclined by 20°.

5. An assembly as recited in claim 1 wherein the columns are formed from trussed legs.

6. An assembly as recited in claim 1 wherein the area defined by the columns is a carport for shading a car.

7. An assembly as recited in claim 6 further comprising means for connecting the car to the photovoltaic cells to charge the car with electricity.

8. An assembly as recited in claim 1 wherein each leg is identical to each other leg.

9. An assembly as recited in claim 1 wherein the columns are distanced from one another to define a plurality of areas, wherein the truss assembly comprises a plurality of truss assemblies dimensioned for suspension between adjacent columns, wherein the rack comprises a plurality of racks, with each rack mounted to a respective truss assembly, and wherein the plurality of cells are supported by the plurality of racks to block sunlight to shade the areas.

10. A kit for constructing modules for providing shade and for generating electricity comprising:
a plurality of columns, with the columns being positionable on the ground and distanced from one another to define an area;
a truss assembly dimensioned for suspension between adjacent columns;
a rack for mounting on the truss assembly, with said rack providing an open roof for the area; and
a plurality of photovoltaic cells for converting solar energy into electricity, with said plurality of cells being supportable by the rack to close the roof and block sunlight to shade the area.

11. A kit as recited in claim 10 wherein the columns and the truss assembly form conduits, with said kit further comprising a cable for passage through the conduits for electrical connection to the photovoltaic cells.

12. A kit as recited in claim 11 wherein the area defined by the columns is a carport for shading a car, and wherein the cable can be electrically connected to the car to charge the car with electricity.

13. A kit as recited in claim 10 wherein the plurality of photovoltaic cells are provided in a plurality of solar panels.

14. A method for providing shade and for generating electricity comprising the steps of:
providing a kit including a plurality of columns, a truss assembly, a rack, and a plurality of photovoltaic cells for converting solar energy into electricity;
erecting four columns at a distance from one another to define an area;
suspending the truss assembly between the columns;
mounting the rack to the truss assembly to form an open roof; and
arranging the plurality of photovoltaic cells on the rack to close the roof and block sunlight to shade the area.

15. A method as recited in claim 14 wherein the columns and the truss assembly form conduits that are aligned as a result of the erecting and suspending steps, wherein the kit further includes a cable, and wherein the method further includes the step of positioning the cable in the conduits and electrically connecting the cable to the photovoltaic cells.

16. A method as recited in claim 15 wherein the area defined by the columns is a carport for shading a car.

17. A method as recited in claim 16 further comprising the step of electrically connecting the car to the cable to charge the car with electricity.

18. A method as recited in claim 14 wherein the rack defines a plurality of sections inclined by 20° and wherein the arranging step is accomplished by putting segments of photovoltaic cells on each section.

19. A method as recited in claim 14 wherein the truss assembly supports the rack at an incline of 10°.

20. A method as recited in claim 14 wherein the kit includes a plurality of truss assemblies and a plurality of racks, and wherein the method further comprises the steps of:
erecting a pair of columns at a distance from one another and from two erected columns to define an additional area between the four respective columns;
suspending a truss assembly between the four respective columns;
mounting a rack to the truss assembly between the four respective columns to form an open roof; and
arranging photovoltaic cells on the respective rack to close the respective roof and block sunlight to shade the additional area.
